(19) United States
(12) Patent Application Publication
(10) Pub. No.: US 2026/0011664 A1
(43) Pub. Date: Jan. 8, 2026

(54) SEMICONDUCTOR CHIP AND METHOD FOR CONNECTING A SEMICONDUCTOR CHIP TO A CONNECTION CARRIER WITH A REDUCED RISK OF SHORT-CIRCUITS BETWEEN ELECTRICAL CONTACT POINTS

(71) Applicant: ams-OSRAM International GmbH, Regensburg (DE)

(72) Inventors: Klaus MÜLLER, Pettendorf (DE); Gerhard HOLZAPFEL, Rain (DE); Peter KELLNER, Maxhütte-Haidhof (DE)

(21) Appl. No.: 18/710,515

(22) PCT Filed: Nov. 7, 2022
(86) PCT No.: PCT/EP2022/080922

§ 371 Date: May 15, 2024

(30) Foreign Application Priority Data
Nov. 19, 2021 (DE) 102021130307.9

(51) Int. Cl. H01L 23/00

(52) U.S. Cl. CPC H01L 24/05; H01L 24/16; H01L 24/81; H01L 24/04; H01L 2224/0401; H01L 2224/0508; H01L 2224/05111; H01L 2224/05144; H01L 2224/05155; H01L 2224/05166; H01L 2224/05169; H01L 2224/05573; H01L 2224/05644; H01L 2224/16227; H01L 2224/16238; H01L 2224/81048; H01L 2224/81192; H01L 2224/81815

(57) ABSTRACT

A semiconductor chip having at least two electrical contact points which are arranged on a main surface of the semiconductor chip is disclosed, a metallic reservoir layer being applied over the entire surface over or on the electrical contact point. A diffusion barrier layer is applied in direct contact on the metallic reservoir layer, the diffusion barrier layer being arranged offset with respect to the metallic reservoir layer, so that the metallic reservoir layer is partially freely accessible. In this case, the diffusion barrier layer forms an adhesion surface for a solder and/or a first solder component of the solder and/or a second solder component of the solder. Methods for connecting a semiconductor chip to a connection carrier are also given.

A semiconductor chip and methods for connecting a semiconductor chip to a connection carrier are disclosed.

An improved method is to be provided, with which in particular semiconductor chips can be connected to a connection carrier with at least two electrical contact points that are comparatively close together. In particular, the method is intended to at least reduce the risk of short circuits between the electrical contact points.

Furthermore, a semiconductor chip is to be provided that can be connected to a connection carrier in a simplified manner. In particular, a semiconductor chip is to be provided that can be connected to a connection carrier without short circuits.

These tasks are solved by a semiconductor chip with the features of patent claim 1, by a method with the steps of patent claim 10 and by a method with the steps of patent claim 11.

Advantageous embodiments of the semiconductor chip and the methods are given in the respective dependent claims.

According to an embodiment, the semiconductor chip comprises at least two electrical contact points arranged on a main surface of the semiconductor chip. In particular, the two electrical contact points are configured to be externally electrically contacted and/or mechanically connected in a stable manner to electrical connection points. With the help of the two electrical contact points, it is possible to inject current into the semiconductor chip during operation.

The electrical contact point comprises, for example, an electrical contact layer or is formed from an electrical contact layer.

Preferably, the electrical contact layer comprises a metal or is formed from a metal. For example, the electrical contact layer comprises one of the following materials or is formed from one of the following materials: copper (Cu), platinum (Pt), gold (Au), titanium (Ti), chromium (Cr).

In particular, it is also possible for the electrical contact layer to comprise one or more individual layers or to be formed from one or more individual layers. For example, the electrical contact layer has an adhesion-promoting individual layer, which, in particular, increases the adhesion of the electrical contact layer to the directly adjacent material of the semiconductor chip. For example, titanium is a suitable material for an adhesion-promoting individual layer of the electrical contact layer.

The electrical contact layer has, for example, a thickness of between and including 20 nanometers and 100 nanometers or between and including 20 nanometers and 40 nanometers.

According to a further embodiment of the semiconductor chip, a metallic reservoir layer is applied over or on the entire surface of the electrical contact point. In other words, the metallic reservoir layer preferably covers the electrical contact point completely.

Here and in the following, the term “over” means, in particular, that the elements placed in structural relationship to each other by this term do not necessarily have to be in direct contact with each other, but that further elements can be arranged in between.

In particular, the metallic reservoir layer comprises a metal or is formed from a metal. The metal is, for example, gold (Au). Furthermore, the metallic reservoir layer has, for example, a thickness of between and including 1 micrometer and 5 micrometers or between and including 2 micrometers and 4 micrometers.

According to a further embodiment of the semiconductor chip, a diffusion barrier layer is applied in direct contact with the metallic reservoir layer, the diffusion barrier layer is arranged offset to the metallic reservoir layer so that the metallic reservoir layer is partially freely accessible.

The diffusion barrier layer is particularly suitable for forming an adhesion surface for a solder. The diffusion barrier layer is therefore particularly well wettable for a solder. Furthermore, the diffusion barrier layer reduces or minimizes the penetration of solder. In particular, the diffusion barrier layer represents a barrier for the diffusion of the solder. In particular, the diffusion barrier layer is stable with respect to the solder.

According to an embodiment of the semiconductor chip, the diffusion barrier layer is arranged centrally on the metallic reservoir layer, so that lateral areas of the surface of the metallic reservoir layer are freely accessible.

The diffusion barrier layer comprises, for example, one of the following materials or is formed from one of the following materials: nickel (Ni), platinum (Pt).

Furthermore, it is also possible for the diffusion barrier layer to comprise one or more individual layers or to be formed from one or more individual layers. For example, the diffusion barrier layer comprises an adhesion-promoting individual layer, which, in particular, increases the adhesion of the diffusion barrier layer to the reservoir layer. For example, titanium is suitable as a material for an adhesion-promoting individual layer of the diffusion barrier layer.

For example, the diffusion barrier layer has a thickness of between and including 100 nanometers and 1 micrometer or between and including 200 nanometers and 700 nanometers. In particular, an adhesion-promoting individual layer of the diffusion barrier layer, for example made of titanium, has a thickness of between and including 20 nanometers and 100 nanometers.

According to a preferred embodiment, the semiconductor chip comprises at least two electrical contact points which are arranged on a main surface, the metallic reservoir layer being applied over or on the entire surface of the electrical contact point. In addition, the diffusion barrier layer is applied in direct contact with the metallic reservoir layer, the diffusion barrier layer being arranged offset relative to the metallic reservoir layer so that the metallic reservoir layer is partially freely accessible. The diffusion barrier layer forms an adhesion surface for the solder and/or a first solder component and/or a second solder component.

As a rule, the solder is a metal alloy of at least two metals, which are also referred to as solder components in the present case. For example, the solder comprises a first solder component and a second solder component or is formed from a first solder component and a second solder component. For example, the solder is a eutectic solder. A eutectic solder is an alloy of at least two metal solder components, wherein the alloy has a lower melting temperature than the solder components forming it. In other words, a eutectic solder solidifies at a lower melting temperature than the solder components that form it. For example, the solder is a gold-tin eutectic solder. A gold-tin eutectic solder has gold as the high-melting solder component and tin (Sn) as the low-melting solder component. The term “high-melting solder component” means, in particular, that the melting temperature of the solder component so designated is lower than the melting temperature of the other solder component, which is consequently referred to as a low-melting solder component.

According to a further embodiment of the semiconductor chip, a separation layer is applied in direct contact with the metallic reservoir layer, separation layer being offset arranged from the metallic reservoir layer so that the metallic reservoir layer is partially freely accessible. The separation layer is also preferably arranged centrally on the metallic reservoir layer, so that lateral areas of the metallic reservoir layer are freely accessible.

According to a further embodiment of the semiconductor chip, the separation layer is soluble in the solder and/or the first solder component of the solder and/or the second solder component of the solder. By this is meant, in particular, that material of the separation layer enters the solder or one of its components when the solder or one of its components is in liquid form in direct contact with the separation layer.

The separation layer comprises, for example, titanium or is formed from titanium. The separation layer has, for example, a thickness of between and including 20 nanometers and 40 nanometers.

According to a preferred embodiment, the semiconductor chip comprises at least two electrical contact points which are arranged on a main surface, wherein the metallic reservoir layer is applied over or on the entire surface of the electrical contact point. Furthermore, a separation layer is applied in direct contact with the metallic reservoir layer, the separation layer being arranged offset relative to the metallic reservoir layer so that the metallic reservoir layer is partially freely accessible. Finally, the separation layer is soluble in the solder and/or the first solder component of the solder and/or the second solder component of the solder.

In particular, the semiconductor chip is based on the idea of applying a further layer, such as the diffusion barrier layer or the separation layer, to the metallic reservoir layer in a offset position so that the metallic reservoir layer is partially freely accessible. In this way, solder can be collected on the exposed areas of the metallic reservoir layer when they are pressed together during a subsequent joining process. In particular, excess solder can solidify on the exposed areas of the metallic reservoir layer. This at least reduces the probability of short circuits between the electrical contact points during soldering.

According to a further embodiment of the semiconductor chip, a metallic end layer is arranged over or on the diffusion barrier layer and/or over or on the separation layer. Preferably, the metallic end layer completely covers the diffusion barrier layer and/or the separation layer. In other words, the metallic end layer is preferably arranged over or on the entire surface of the diffusion barrier layer and/or of the separation layer.

The metallic end layer preferably prevents oxidation of the underlying material. Preferably, the end layer partially forms an outer surface of the chip. For example, the metallic end layer is formed from gold or comprises gold. Furthermore, the metallic end layer preferably has a thickness of between and including 50 nanometers and 250 nanometers.

According to a further embodiment of the semiconductor chip, the diffusion barrier layer is applied in direct contact with the metallic reservoir layer. In addition, the metallic end layer is arranged over or on the diffusion barrier layer. Furthermore, the solder is arranged over or on the metallic end layer. In particular, the solder is configured for soldering and is intended to connect the semiconductor chip to another element, for example to a connection carrier that has external connection points, in an electrically conducting and mechanically stable manner.

According to a further embodiment of the semiconductor chip, the metallic reservoir layer, the metallic end layer and/or at least one solder component comprises the same material or are formed from the same material. For example, the metallic reservoir layer, the metallic end layer and/or the solder component are made of gold.

According to a further embodiment of the semiconductor chip, a solder component layer comprising the second solder component is arranged over or on the separation layer. In other words, the semiconductor chip preferably has a separation layer, which is arranged in direct contact on the metallic reservoir layer. The solder component layer, which has the second solder component or is formed from the second solder component, is arranged over or on the separation layer. The solder component layer preferably covers the separation layer completely. In other words, in this embodiment, the solder component layer is also arranged offset from the metallic reservoir layer. In this embodiment, the metallic reservoir layer preferably has the first solder component of the solder, which together with the second solder component forms a solder, in particular a eutectic solder. For example, the first solder component of the metallic reservoir layer is the high-melting solder component, such as gold, and the second solder component is the low-melting solder component, such as tin.

In this embodiment of the semiconductor chip, the solder components for forming a solder are advantageously integrated in a layer sequence which is applied to the electrical contact point. Furthermore, the separation layer and the solder component layer are arranged offset from the metallic connection layer, so that the probability of short circuits occurring between the electrical contact points during joining is at least reduced.

The second solder component layer has a thickness of between and including 1 micrometer and 2 micrometers, for example.

According to an embodiment of the semiconductor chip, a further separation layer is arranged over or on the solder component layer. Like the separation layer, the further separation layer is also preferably soluble in the solder and/or the first solder component of the solder and/or the second solder component of the solder.

The further separation layer comprises titanium, for example, or is formed from titanium. Preferably, the further separation layer is thinner than the separation layer. For example, the further separation layer has a thickness of between and including 5 nanometers and 10 nanometers.

According to a further embodiment of the semiconductor chip, a layer sequence is applied in direct contact to the electrical contact point, which comprises or consists of the following layers in the specified order, as viewed from the electrical contact point:
metallic reservoir layer,
diffusion barrier layer, and
metallic end layer.

According to a further embodiment of the semiconductor chip, a layer sequence is applied in direct contact to the electrical contact point, which comprises or consists of the following layers in the specified order, as viewed from the electrical contact point:
metallic reservoir layer comprising a high-melting first solder component,
separation layer,
solder component layer comprising a low-melting second solder component.

According to a further embodiment of the semiconductor chip, a layer sequence is applied to the electrical contact point in direct contact, which comprises the following layers in the specified order as seen from the electrical contact point:
metallic reservoir layer comprising the first solder component, which is preferably low-melting,
separation layer,
solder component layer comprising the second solder component, which is preferably high-melting,
further separation layer,
metallic end layer.

According to a further embodiment of the semiconductor chip, the electrical contact points have a distance of at most 50 micrometers, of at most 20 micrometers or of at most 10 micrometers.

According to a further embodiment, the semiconductor chip is a laser diode chip or a light emitting diode chip. In particular, the radiation emitting semiconductor chip is a flip chip.

The radiation emitting semiconductor chip comprises an epitaxial semiconductor layer sequence with an active layer that generates electromagnetic radiation during operation. The epitaxial semiconductor layer sequence is epitaxially grown on a growth substrate and is, according to an embodiment, part of the finished radiation-emitting semiconductor chip. Furthermore, it is also possible that the radiation-emitting semiconductor chip has a carrier instead of the growth substrate, which mechanically stabilizes the radiation-emitting semiconductor chip. In particular, the radiation-emitting semiconductor chip has two electrical contacts that are configured for the current impression in the active layer. If the two electrical contacts are arranged on a common main surface of the radiation-emitting semiconductor chip, it is a semiconductor chip in flip-chip design.

According to an embodiment of the semiconductor chip, the separation layer is arranged centrally on the metallic reservoir layer, so that lateral areas of the metallic reservoir layer are freely accessible. For example, the freely accessible areas of the metallic reservoir layer completely surround the separation layer. For example, the metallic reservoir layer and the separation layer have a stepped profile in sectional view, which tapers starting from the metallic reservoir layer.

According to an embodiment of the semiconductor chip, the diffusion barrier layer is arranged centrally on the metallic reservoir layer, so that lateral areas of the metallic reservoir layer are freely accessible. For example, the freely accessible areas of the metallic reservoir layer completely surround the diffusion barrier layer. For example, the metallic reservoir layer and the diffusion barrier layer have a step-shaped profile in sectional view, which tapers starting from the metallic reservoir layer.

The semiconductor chip is particularly configured for connecting to a connection carrier. In the method described below, the semiconductor chip already described is used in particular. All embodiments and features already described in connection with the semiconductor chip can also be embodied in the method and vice versa.

According to an embodiment of the method, a semiconductor chip with at least two electrical contact points arranged on a main surface is provided. In other words, it is a semiconductor chip with a flip-chip design.

According to a further embodiment of the method, a connection carrier with two electrical connection points is provided.

For example, the connection carrier comprises a substrate, wherein the electrical connection points are arranged on a main surface of the substrate. For example, the substrate comprises ceramics or is formed from ceramics.

According to a further embodiment of the method, a solder is applied over or on the electrical connection points of the connection carrier and/or over or on the electrical contact points of the semiconductor chip.

According to a further embodiment of the method, the solder is liquefied. For example, the solder can be liquefied by heating the element to which the solder is applied, such as the connection carrier or the semiconductor chip.

According to a further embodiment of the method, the semiconductor chip is placed on the connection carrier. In particular, the electrical connection points of the semiconductor chip are positioned over the electrical connection points of the connection carrier. In particular, the electrical connection points of the connection carrier and the solder and the electrical contact points of the semiconductor chip and the solder are in contact. For example, the semiconductor chip and the connection carrier are pressed together.

In particular, a metallic reservoir layer is applied on the entire surface of the electrical contact point, wherein a diffusion barrier layer is applied in direct contact with the metallic reservoir layer, which is arranged offset to the metallic reservoir layer so that the metallic reservoir layer is partially freely accessible. The diffusion barrier layer is configured as an adhesion surface for the solder.

According to a further embodiment of the method, liquid solder hits the metallic reservoir layer and solidifies there.

According to a preferred embodiment, the method comprises the following steps:
providing a semiconductor chip with at least two electrical contact points arranged on a main surface,
providing a connection carrier with two electrical connection points,
applying a solder over or on the electrical connection points of the connection carrier and/or over or on the electrical contact points of the semiconductor chip,
liquefying the solder,
placing the semiconductor chip on the connection carrier, wherein
a metallic reservoir layer is applied on the entire surface of the electrical contact point,
a diffusion barrier layer is applied in direct contact with the metallic reservoir layer, which is arranged offset to the metallic reservoir layer so that the metallic reservoir layer is partially freely accessible,
the diffusion barrier layer forms an adhesion surface for the solder,
liquid solder hits the metallic reservoir layer and solidifies.

In particular, the steps of the method are carried out in the order indicated. In particular, however, liquefying the solder and placing the semiconductor chip can also take place in reverse order. In other words, the semiconductor chip can also be placed on the connection carrier first and then the solder can be liquefied.

In the method described above, the diffusion barrier layer is provided, in particular, on the metallic reservoir layer. The diffusion barrier layer prevents the liquid solder from coming into contact with the metallic reservoir layer. At the same time, when the semiconductor chip is placed and/or pressed onto the liquid solder, liquid solder is prevented from escaping laterally and forming a short circuit between two directly adjacent electrical contact points of the semiconductor chip. The liquid solder finds areas where it can solidify, particularly on the exposed surfaces of the metallic reservoir layer.

According to an embodiment of the method, a metallic reservoir layer is arranged over or on the electrical contact point, the metallic reservoir layer comprises a first solder component or consists of a first solder component.

In a further embodiment of the method, a separation layer is applied in direct contact with the metallic reservoir layer, which is arranged offset to the metallic reservoir layer so that the metallic reservoir layer is partially freely accessible. In particular, the separation layer solves into the solder or one of its components if these are present in liquid form.

According to a further embodiment of the method, a solder component layer with a second solder component is arranged over or on the separation layer.

According to a further embodiment of the method, the first solder component and/or the second solder component are liquefied and the separation layer partially or completely dissolves in the first solder component and/or the second solder component.

According to a preferred embodiment, the method comprises the following steps:
providing a semiconductor chip with at least two electrical contact points arranged on a main surface,
providing a connection carrier with two electrical connection points,
placing the semiconductor chip on the connection carrier, wherein
a metallic reservoir layer comprising a first solder component is applied over or on the entire surface of the electrical contact point,
a separation layer is applied in direct contact with the metallic reservoir layer, the separation layer is arranged offset to the metallic reservoir layer so that the metallic reservoir layer is partially freely accessible,
a solder component layer comprising a second solder component is arranged over or on the separation layer,
the first solder component and/or the second solder component are liquefied, wherein the separation layer dissolves in the first solder component and/or the second solder component.

According to a further embodiment of the method, the connection carrier is heated. For example, the semiconductor chip is placed on electrical connection points of the connection carrier, wherein the connection carrier is heated. In this case, the layer sequence on the electrical contact points of the semiconductor chip heats up starting from the connection carrier. In other words, the solder component layer first liquefies with the second solder component and the separation layer becomes permeable for the second solder component, so that the first solder component and the second solder component come into contact and form a liquid solder.

According to a further embodiment of the method, the first solder component is gold (Au) and the second solder component is tin (Sn). In this case, it is, in particular, an AuSn eutectic solder. Au forms the first, high-melting solder component with a higher melting temperature, while Sn forms the second, low-melting solder component with a lower melting temperature.

According to a further embodiment of the method, the electrical connection point of the connection carrier has an electrical contact layer over or on which a diffusion barrier layer is arranged, which forms an adhesion surface for the solder.

According to a further embodiment of the method, the electrical connection point of the connection carrier has an electrical contact layer over or on which a metallic end layer is arranged.

In the following, the semiconductor chip and the methods for connecting the semiconductor chip are described in more detail in connection with the figures.

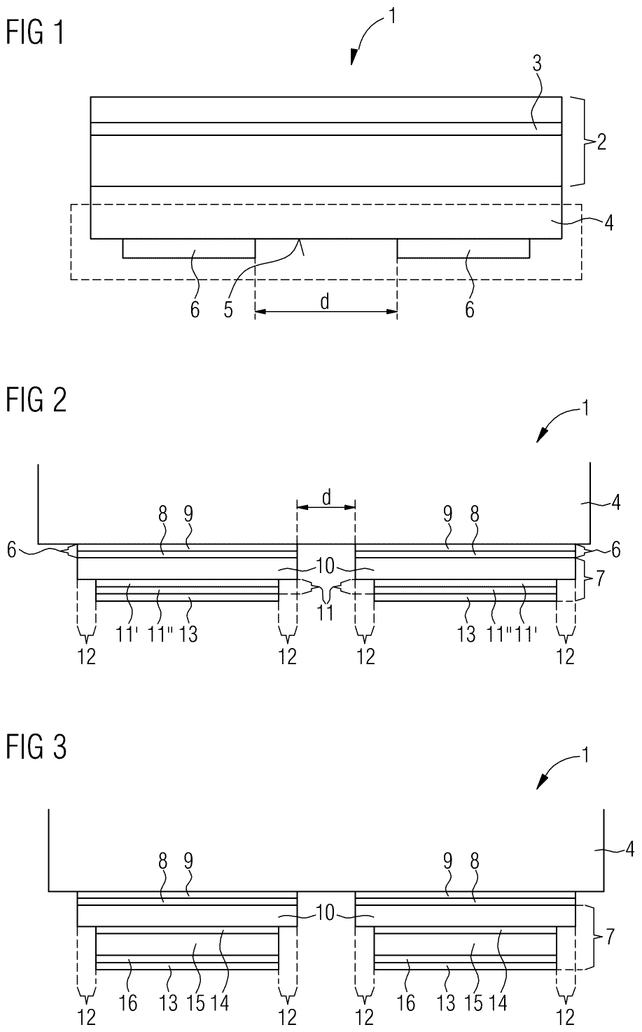

FIGS. 1 to 3 show schematic sectional views of semiconductor chips according to various exemplary embodiments.

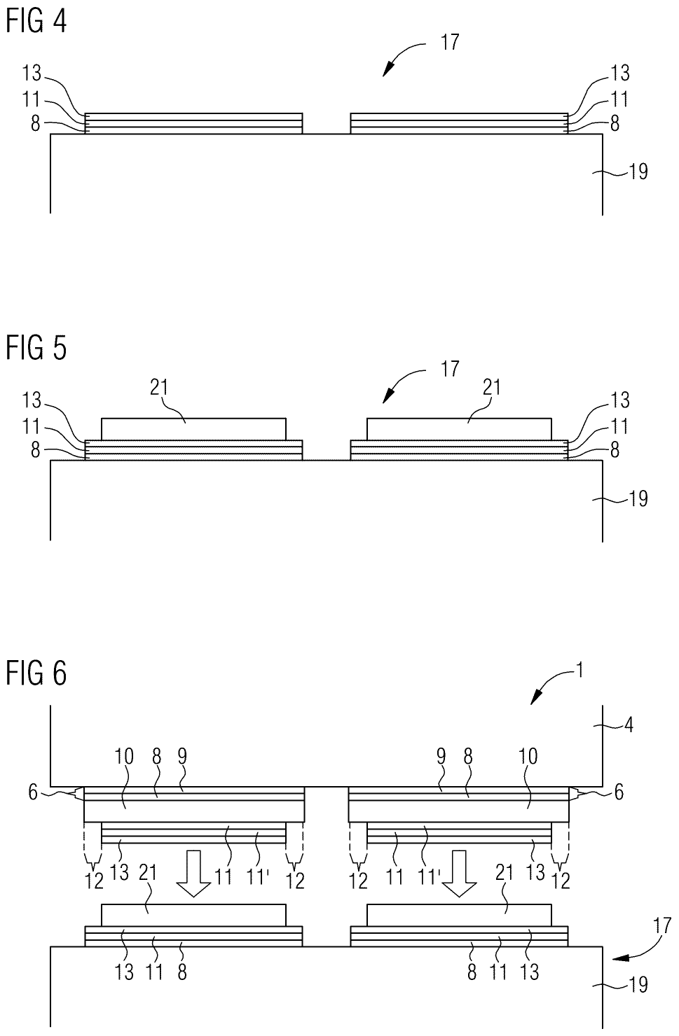

FIGS. 4 to 7 show schematic sectional views of stages of a method according to an exemplary embodiment.

FIG. 8 shows a schematic sectional view of a stage of a method according to a further exemplary embodiment.

Elements that are identical, similar or have the same effect are marked with the same reference symbols in the figures. The figures and the proportions of the elements shown in the figures are not to be regarded as true to scale. Rather, individual elements, in particular layer thicknesses, may be shown in exaggerated size for better visualization and/or understanding.

The semiconductor chip 1 according to the exemplary embodiment of FIG. 1 is designed as a radiation-emitting semiconductor chip 1. In particular, the semiconductor chip 1 according to FIG. 1 is a light-emitting diode chip in flip-chip design. The semiconductor chip 1 according to the exemplary embodiment of FIG. 1 has an epitaxial semiconductor layer sequence 2 with an active layer 3, which is suitable for generating electromagnetic radiation during operation. The epitaxial semiconductor layer sequence 2 is applied to a carrier 4. The carrier 4 is designed, for example, as a growth substrate for the epitaxial semiconductor layer sequence 2. Two electrical contact points 6 are arranged on a main surface 5 of the semiconductor chip 1. The electrical contact points 6 have, for example, a distance d of less than or equal to 50 micrometers, less than or equal to 20 micrometers or less than or equal to 10 micrometers from each other.

FIG. 2 shows the electrical contact points 6 and a layer sequence 7 on the electrical contact points 6 of the section marked in FIG. 1 according to an exemplary embodiment.

In the semiconductor chip according to the exemplary embodiment in FIG. 2, the electrical contact points 6 are formed as a layer sequence comprising an electrical contact layer 8 and an adhesion-promoting individual layer 9. The adhesion-promoting individual layer 9 increases the adhesion of the electrical contact point 6 to the carrier 4. For example, the adhesion-promoting individual layer 9 comprises titanium or is formed from titanium.

The electrical contact layer 8 is arranged on the adhesion-promoting individual layer 9 of the electrical contact point 6. The electrical contact layer 8 is made of copper, platinum, gold, silver or aluminum, for example.

A metallic reservoir layer 10 is applied over the entire surface of the electrical contact layer 8 in direct contact. The metallic reservoir layer 10 is laterally flush with the electrical contact point 6. In other words, the metallic reservoir layer 10 does not protrude laterally beyond the electrical contact point 6. The metallic reservoir layer 10 is formed from gold in the present case and has a comparatively large thickness of a few micrometers.

A diffusion barrier layer 11 is applied in direct contact with the metallic reservoir layer 10. In the present case, the diffusion barrier layer 11 has two individual layers 11′, 11″, an adhesion-promoting individual layer 11′ and an individual layer 11″, which in particular achieves the diffusion barrier properties of the diffusion barrier layer. The adhesion-promoting individual layer 11′ is arranged in direct contact with the metallic reservoir layer 10 and increases the adhesion to the metallic reservoir layer 10. For example, the adhesion-promoting individual layer 11′ comprises titanium. The other individual layer 11″ of the diffusion barrier layer is made of nickel or platinum, for example.

The diffusion barrier layer 11 is arranged centrally of the metallic reservoir layer 10, so that lateral areas 12 of the metallic reservoir layer 10 are freely accessible.

A metallic end layer 13, which is formed from gold in the present case, is applied to the diffusion barrier layer 11 in direct contact. The metallic end layer 13 completely covers the diffusion barrier layer 11, but does not protrude beyond it.

FIG. 3 shows the electrical contact points 6 and a layer sequence 7 on the electrical contact points 6 of the section marked in FIG. 1 according to a further exemplary embodiment.

In the semiconductor chip 1 according to FIG. 3, as in the semiconductor chip 1 according to the exemplary embodiment of FIG. 2, the electrical contact point 6 is formed by an adhesion-promoting individual layer 9 and an electrical contact layer 8.

A metallic reservoir layer 10 is applied in direct contact with the electrical contact layer 8, which completely covers the electrical contact layer 8 but does not protrude beyond the electrical contact layer 8. The metallic reservoir layer 10 is formed from a first solder component of a solder. The metallic reservoir layer 10 is formed from gold in the present case.

A separation layer 14 is applied in direct contact with the metallic reservoir layer 10. The separation layer 14 is formed, for example, from titanium and has a thickness of between and including 20 nanometers and 40 nanometers.

In the present case, the separation layer 14 is arranged centrally on the metallic reservoir layer 10 and is also arranged offset relative to the metallic reservoir layer 10, so that lateral areas 12 of the metallic reservoir layer 10 are freely accessible. In other words, the separation layer 14 has a smaller cross-sectional area than the metallic reservoir layer 10.

A solder component layer 15, which comprises a second solder component of the solder, is applied in direct contact with the separation layer 14. The solder component layer 15 is applied over the entire surface of the separation layer 14 and does not protrude beyond it. In the present case, the second solder component layer 15 is made of tin. For example, the solder component layer 15 has a thickness of between and including 1 micrometer and 2 micrometers.

A further separation layer 16 is applied in direct contact with the solder component layer 15. The further separation layer 16 is also formed from titanium in the present case and has a thickness of between and including 5 nanometers and 10 nanometers. In particular, the further separation layer 16 has a lower thickness than the separation layer 14.

A metallic end layer 13 is applied over the entire surface in direct contact with the further separation layer 16 to protect against oxidation. In the present case, the metallic end layer 13 is made of gold.

In the method according to the exemplary embodiment of FIGS. 4 to 7, a semiconductor chip 1 is provided (not shown), as already described with reference to FIG. 2.

Furthermore, a connection carrier 17 with two electrical connection points 18 is provided (FIG. 4). In the present case, the connection carrier 17 has a substrate 19, which is formed from ceramic. Two electrical contact layers 8 are applied to a main surface of the substrate 19, which in the present case each form an electrical connection point 18. A diffusion barrier layer 11 is applied to the electrical connection point 18, which in the present case forms an adhesion surface for a solder. A thin metallic end layer 13, which is formed from gold in the present case, is applied in direct contact with the diffusion barrier layer 11.

In the next step, a solder 21 is applied over the electrical connection points 18 of the connection carrier 17 (FIG. 5). Alternatively, it is also possible for the solder 21 to be applied over the electrical contact points 6 of the semiconductor chip 1 (not shown here).

In a further step, the semiconductor chip 1 is lowered so that at least the layer sequence 7 on the electrical contact points 6 comes into direct contact with the solder 21, which is present in liquid form (FIG. 6). For example, the solder 21 is heated by heating the substrate 19 of the connection carrier 17. If the semiconductor chip 1 is now pressed onto the liquid solder 21, solder 21 escapes laterally, wets lateral areas 12 of the metallic reservoir layer 10 and solidifies there.

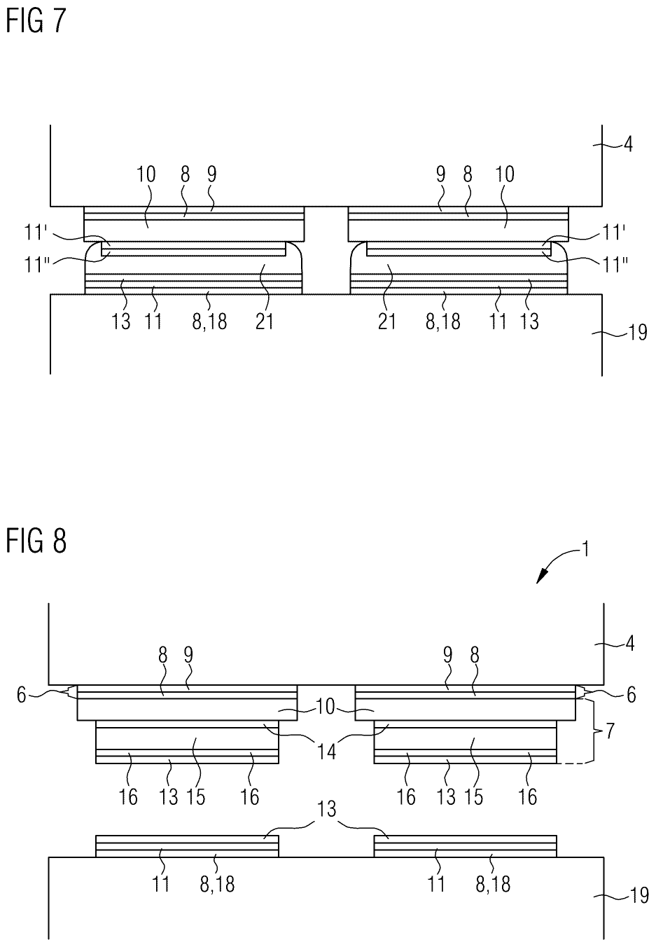

Furthermore, the diffusion barrier layer 11 forms an adhesion surface for the solder 21, so that a mechanically stable connection is created between the connection carrier 17 and the semiconductor chip 1. Furthermore, the process usually at least partially liquefies the metallic end layer 13 and is absorbed by the solder 21 (FIG. 7).

In the method according to the exemplary embodiment of FIG. 8, a semiconductor chip 1 is used as already described with reference to FIG. 3. The connection carrier 17 is designed as already described with reference to FIG. 4.

In contrast to the method according to the exemplary embodiment of FIGS. 4 to 7, no additional solder 21, which is applied over or onto the electrical connection points 18 of the connection carrier 17 or over or onto the electrical contact points 6 of the semiconductor chip 1, is used in the method according to the exemplary embodiment of FIG. 8. Rather, the material from which the solder connection is formed is already integrated in the layer sequence 7 on the electrical contact point 6 of the semiconductor chip 1.

In the method according to the exemplary embodiment of FIG. 8, the semiconductor chip 1 is lowered onto the connection carrier 17 so that the layer sequence 7 on the electrical contact points 6 comes to rest on the layer sequence on the electrical connection points 18 of the connection carrier 17.

The connection carrier 17 is heated before or after the semiconductor chip 1 is lowered so that the metallic reservoir layer 10 and the metallic solder component layer 15 at least partially liquefy.

During liquefaction, the material of the metallic separation layer 13 penetrates the further separation layer 16 and liquefies together with the material of the solder component layer 15. Furthermore, the material of the separation layer 14 and the material of the metallic reservoir layer 10 also liquefy, so that an initially liquid mixture of a first solder component and a second solder component of a eutectic gold-tin solder is formed on the electrical contact layer 8. As this is a eutectic solder, the mixture solidifies quickly.

In particular, short circuits between the electrical contact points 6 of the semiconductor chip 1 are reduced in both of the present methods, since the liquid melt of the solder 21 can wet the exposed areas 12 of the metallic reservoir layer 10 and solidify there.

The present application claims the priority of the German application DE 102021130307.9, the disclosure of which is hereby incorporated by reference.

The invention is not limited to the description based on the exemplary embodiments. Rather, the invention includes any new feature as well as any combination of features, which includes in particular any combination of features in the patent claims, even if this feature or combination itself is not explicitly stated in the patent claims or exemplary embodiments.

### LIST OF REFERENCE SYMBOLS

1 semiconductor chip
2 epitaxial semiconductor layer sequence
3 active layer
4 carrier
5 main surface of the semiconductor chip
6 electrical contact point
7 layer sequence
8 electrical contact layer
9 adhesive-promoting individual layer
10 metallic reservoir layer
11 diffusion barrier layer
11′, 11″ individual layer
12 lateral area
13 metallic end layer
14 separation layer
15 solder component layer
16 further separation layer
17 connection carrier
18 electrical connection point
19 substrate
20 electrical contact layers
21 solder
D distance

1. Semiconductor chip comprising:
at least two electrical contact points arranged on a main surface of the semiconductor chip, wherein
a metallic reservoir layer is applied over or on an entire surface of the electrical contact point,
wherein
a separation layer is applied in direct contact with the metallic reservoir layer, the separation layer being offset relative to the metallic reservoir layer, so that the metallic reservoir layer is partially freely accessible, and
the separation layer is soluble in the solder and/or a first solder component of the solder and/or a second solder component of the solder.

2. Semiconductor chip according to claim 1,
wherein a metallic end layer is arranged over or on the separation layer.

3. (canceled)

4. (canceled)

5. Semiconductor chip according to claim 1,
wherein a solder component layer comprising the second solder component is arranged over or on the separation layer.

6. Semiconductor chip according to claim 5,
wherein a further separation layer is arranged over or on the solder component layer.

7. Semiconductor chip according claim 1, wherein a layer sequence is applied in direct contact to the electrical contact point, comprising the following layers in the indicated order as seen from the electrical contact point:
metallic reservoir layer comprising a first solder component,
separation layer,
solder component layer comprising a second solder component,
further separation layer,
metallic end layer.

8. Semiconductor chip according to claim 1,
wherein the electrical contact points have a distance of at most 50 micrometers.

9. Semiconductor chip according to claim 1,
which is a radiation-emitting semiconductor chip in flip-chip design.

10. (canceled)

11. Method for connecting a semiconductor chip to a connection carrier, comprising the following steps:
providing a semiconductor chip with at least two electrical contact points which are arranged on a main surface of the semiconductor chip,
providing a connection carrier with two electrical connection points,
placing the semiconductor chip on the connection carrier,
wherein
a metallic reservoir layer comprising a first solder component is applied over or on the entire surface of the electrical contact point,
a separation layer is applied in direct contact with the metallic reservoir layer, the separation layer being arranged offset relative to the metallic reservoir layer, so that the metallic reservoir layer is partially freely accessible,
a solder component layer comprising a second solder component is arranged over or on the separation layer,
the first solder component and/or the second solder component are liquefied, wherein the separation layer dissolves in the first solder component and/or the second solder component.

12. Method according to claim 11, wherein
the first solder component is Au, and
the second solder component is Sn.

13. Method according to claim 11,
Wherein the electrical connection point of the connection carrier has an electrical contact layer, over or on which a diffusion barrier layer is arranged, which forms an adhesion surface for the solder.

14. Method according to claim 11,
wherein the electrical connection point of the connection carrier has an electrical contact layer, over or on which a metallic end layer is arranged.

15. Method according to claim 11,
wherein the connection carrier is heated.

16. Semiconductor chip according to claim 11, wherein the separation layer is arranged centrally on the metallic reservoir layer, so that lateral areas of the metallic reservoir layer are freely accessible.
